(19) United States
(12) Patent Application Publication
(10) Pub. No.: US 2011/0076117 A1
(43) Pub. Date: Mar. 31, 2011

(54) PROCESS MODULE, SUBSTRATE PROCESSING APPARATUS, AND SUBSTRATE TRANSFERRING METHOD

(75) Inventor: Yoji IIZUKA, Yamanashi (JP)

(73) Assignee: TOKYO ELECTRON LIMITED, Tokyo (JP)

(21) Appl. No.: 12/882,252

(22) Filed: Sep. 15, 2010

(30) Foreign Application Priority Data
Sep. 25, 2009 (JP) 2009-220775

(51) Int. Cl. H01L 21/677; B25J 21/00; B25J 11/00

(52) U.S. Cl. 414/217; 414/222.01; 414/222.13; 414/806

(57) ABSTRACT

A disclosed process module includes a substrate receiving part on which a substrate is placed and a process is carried out with respect to the substrate on the substrate receiving part; and a substrate transfer mechanism including plural substrate holding members, each of which can be positioned in a first position where the substrate is transferred to/from a substrate transfer apparatus provided outside the process module and a second position above the substrate receiving part, wherein each of the substrate holding members can hold the substrate.

### CROSS-REFERENCE TO RELATED APPLICATION

The present application is based on Japanese Priority Application No. 2009-220775 filed Sep. 25, 2009, the entire contents of which are hereby incorporated herein by reference.

### BACKGROUND OF THE INVENTION

1. Field of the Invention

The present invention relates to a process module where a substrate such as a semiconductor wafer is processed, a substrate processing apparatus including the process module, and a substrate transferring method performed in the process module and the substrate processing apparatus.

2. Description of the Related Art

In a fabrication process of semiconductor integrated circuits (ICs), a so-called cluster tool has been used that includes plural process chambers coupled with one another via one transfer chamber (for example, Patent Documents 1, 2). With this, because a substrate can be transferred from one process chamber to another through the transfer chamber where a vacuum environment (or clean environment) is realized, the substrate can be kept in a clean environment when the substrate is transferred, which may improve a production yield by reducing contamination of the substrate. In addition, the plural process chambers are coupled adjacent to one another to the transfer chamber, so that a transfer route along which the substrate is transferred from one process chamber to another can be reduced to minimum. Therefore, throughput can be increased in a reduced period of time of transferring the substrate.

Patent Document 1: Japanese Patent Application Laid-Open Publication No. 2008-258192.

Patent Document 2: Japanese Patent Application Laid-Open Publication No. H07-142551.

With further higher integration of ICs and further reduction of dimensions that enable the higher integration, a thin film deposited on a substrate becomes thinner, and a deposition time becomes shorter accordingly. Therefore, a time required to transfer the substrate into/out from a process chamber becomes longer relative to the deposition time, and thus is likely to limit the throughput even in the cluster tool.

The present invention has been made in view of the above, and provides a process module that can reduce substrate transfer time, thereby contributing to increased throughput, a substrate processing apparatus including the process module, and a substrate transferring method performed in the process module and the substrate processing apparatus.

### SUMMARY OF THE INVENTION

A first aspect of the present invention provides a process module including a substrate receiving part on which a substrate is placed and a process is carried out with respect to the substrate on the substrate receiving part; and a substrate transfer mechanism including plural substrate holding members, each of which can be positioned in a first position where the substrate is transferred to/from a substrate transfer apparatus provided outside the process module and a second position above the substrate receiving part, wherein each of the substrate holding members can hold the substrate.

A second aspect of the present invention provides a substrate processing apparatus including a process module according to the first aspect; and a substrate transfer apparatus that can transfer the substrate to/from one of the plural substrate holding members that is positioned in the first position.

A third aspect of the present invention provides a substrate transfer method of transferring a substrate between a substrate transfer apparatus and a substrate receiving part on which the substrate is placed and a process is carried out with respect to the substrate on the substrate receiving part. The substrate transfer method includes steps of transferring a first substrate using the substrate transfer apparatus to and maintaining the first substrate in a first position; transferring the first substrate maintained in the first position by the substrate transfer apparatus to a first one of plural substrate holding members, each of which can be positioned in the first position and a second position above the substrate receiving part and hold a substrate; moving the first substrate holding member holding the first substrate to the second position; and transferring a second substrate from a second one of the plural substrate holding members to the substrate transfer apparatus that has stayed in the first position.

A fourth aspect of the present invention provides a substrate transfer method of transferring a substrate between a substrate transfer apparatus and a substrate receiving part on which the substrate is placed and a process is carried out with respect to the substrate on the substrate receiving part. The substrate transfer method includes steps of transferring a first substrate held by a first one of plural substrate holding members, each of which can be positioned in a first position and a second position, the second position being above the substrate receiving part, and hold a substrate, to the second position; transferring a second substrate using the substrate transfer apparatus to and maintaining the second substrate in the first position; transferring the second substrate from the substrate transfer apparatus to a second one of the plural substrate holding members in the first position; moving the first substrate holding member holding the first substrate from the second position to the first position; and transferring the first substrate from the first substrate holding member to the substrate transfer apparatus in the first position.

### BRIEF DESCRIPTION OF THE DRAWINGS

FIG. 1 is a schematic view of a substrate processing apparatus according to an embodiment of the present invention;

FIG. 2 is a perspective view schematically illustrating a main substrate transfer mechanism provided in the substrate processing apparatus of FIG. 1;

FIG. 3 is a perspective view schematically illustrating a process module provided in the substrate processing apparatus of FIG. 1 and the main substrate transfer mechanism of FIG. 2;

FIG. 4 provides a plan view (a) and a side view (b) schematically illustrating the process module of FIG. 3;

FIG. 5 provides another plan view (a) and another side view (b) schematically illustrating the process module of FIG. 3;

FIG. 6 provides perspective views for explaining a substrate transfer method according to an embodiment of the present invention;

FIG. 7 provides perspective views for explaining the substrate transfer method according to the embodiment of the present invention, following FIG. 6;

FIG. 8 provides perspective views for explaining a substrate transfer method according to another embodiment of the present invention;

FIG. 9 provides perspective views for explaining the substrate transfer method according to the embodiment of the present invention, following FIG. 8;

FIG. 10 provides perspective views for explaining the substrate transfer method according to the embodiment of the present invention, following FIG. 9;

FIG. 11 provides perspective views for explaining the substrate transfer method according to the embodiment of the present invention, following FIG. 10;

FIG. 12 provides perspective views for explaining the substrate transfer method according to the embodiment of the present invention, following FIG. 11;

FIG. 13 provides perspective views for explaining a substrate transfer method according to yet another embodiment of the present invention;

FIG. 14 provides perspective views for explaining the substrate transfer method according to the embodiment of the present invention, following FIG. 13;

FIG. 15 provides a plan view (a) and a side view (b) schematically illustrating a modified example of the process module illustrated in FIGS. 3 through 6; and

FIG. 16 provides another plan view (a) and another side view (b) of the modified example of FIG. 15.

### DETAILED DESCRIPTION OF THE PREFERRED EMBODIMENT

Non-limiting, exemplary embodiments of the present invention will now be described with reference to the accompanying drawings. In the drawings, the same or corresponding reference symbols are given to the same or corresponding members or components. It is to be noted that the drawings are illustrative of the invention, and there is no intention to indicate scale or relative proportions among the members or components. Therefore, the specific thickness or size should be determined by a person having ordinary skill in the art in view of the following non-limiting embodiments.

### First Embodiment

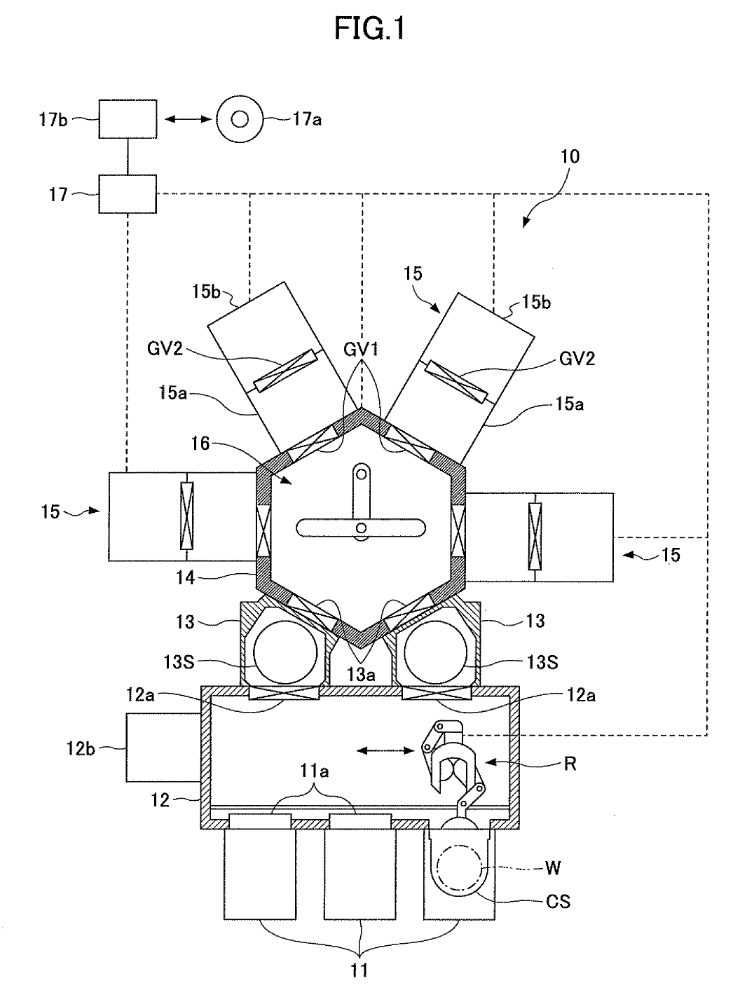

A substrate processing apparatus according to a first embodiment of the present invention is explained with reference to FIGS. 1 through 5.

FIG. 1 is a schematic view illustrating the substrate processing apparatus according to the first embodiment. As shown, a substrate processing apparatus 10 is provided with cassette stages 11 on which a wafer cassette CS such as a Front-Opening Unified Pod is placed, a transfer chamber 12 that is coupled in physical communication with the cassette stages 11 through openings 11a and in which a wafer W may be transferred in an atmospheric environment, load lock chambers 13 whose insides can be maintained at an atmospheric pressure or a reduced pressure and that are coupled to the transfer chamber 12, a transport chamber that is coupled to the load lock chambers 13 and where the wafer W may be transferred in a reduced pressure environment, and process modules 15 that are coupled to the transport chamber 14 and where the wafer W is processed.

A transfer robot R is provided inside the transfer chamber 12. The transfer robot R takes the wafer W out from the wafer cassette CS placed on the cassette stage 11 through the opening 11a to transfer the wafer W to the load lock chamber 13, and takes the wafer W out from the load lock chamber 13 to transfer the wafer W to the wafer cassette CS. In addition, an alignment chamber 12b where the wafer W is aligned is coupled to the transfer chamber 12.

The load lock chambers 13 are provided with susceptors 13S on one of which is placed the wafer W transferred from the transfer chamber 12 or the transport chamber 14 into the corresponding load lock chamber 13. In addition, gate valves 12a are provided between the load lock chambers 13 and the transfer chamber 12, and gate valves 13a are provided between the load lock chambers 13 and the transport chamber 14. When the gate valve 12a and the gate valve 13a are closed, the load lock chamber 13 is kept airtight, and the inside of the load lock chamber 13 can be maintained at atmospheric pressure or at a reduced pressure by an evacuation apparatus and an inert gas (including nitrogen gas) supplying apparatus (not shown) coupled to the load lock chamber 13. When the inside of the load lock chamber 13 is at atmospheric pressure, the gate valve 12a is opened, so that the wafer W is transferred between the load lock chamber 13 and the transfer chamber 12. When the inside of the load lock chamber 13 is at a reduced pressure, the gate valve 13a is opened, so that the wafer W is transferred between the load lock chamber 13 and the transport chamber 14 whose inside has been evacuated to a reduced pressure.

The transport chamber 14 has a hexagonal top-view shape in this embodiment. The load lock chambers 13 are coupled to two faces of the six faces, and the four process modules 15 are coupled to the other four faces. Gate valves GV1 are provided between the transport chamber 14 and the process modules 15. A main transfer apparatus 16 is provided in substantially the center of the transport chamber 14. The main transfer apparatus 16 transfers the wafer W into/out from the load lock chambers 13 or the process modules 15.

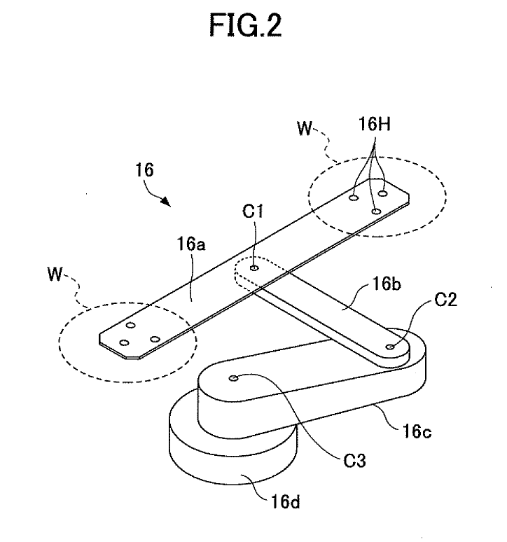

Referring to FIG. 2, the main transfer apparatus 16 includes a transfer arm 16a that has at both end portions wafer holding areas capable of holding the wafers W and can rotate around a rotation axis C1 at substantially the center of the substrate processing apparatus 10; a first supporting arm 16b that rotatably supports the transfer arm 16a at one end and can rotate around a rotation axis C2 at the other end; a second supporting arm 16c that rotatably supports the first supporting arm 16b at one end and can rotate around a rotation axis C3 at the other end; and a base part 16d that rotatably supports the second supporting arm 16c and is arranged in a bottom portion of the transport chamber 14 (FIG. 1). Three suction holes 16H are provided in the wafer holding areas, and thus the wafer W placed on the wafer holding area is held by suction through the suction holes 16H. The transfer arm 16a, the first supporting arm 16b, and the second supporting arm 16c of the main transfer chamber 16 arbitrarily rotate around the corresponding rotation axes C1, C2, and C3, thereby transferring the wafer held by a distal end (wafer holding area) of the transfer arm 16a into a predetermined process module 15 or the load lock chamber 13.

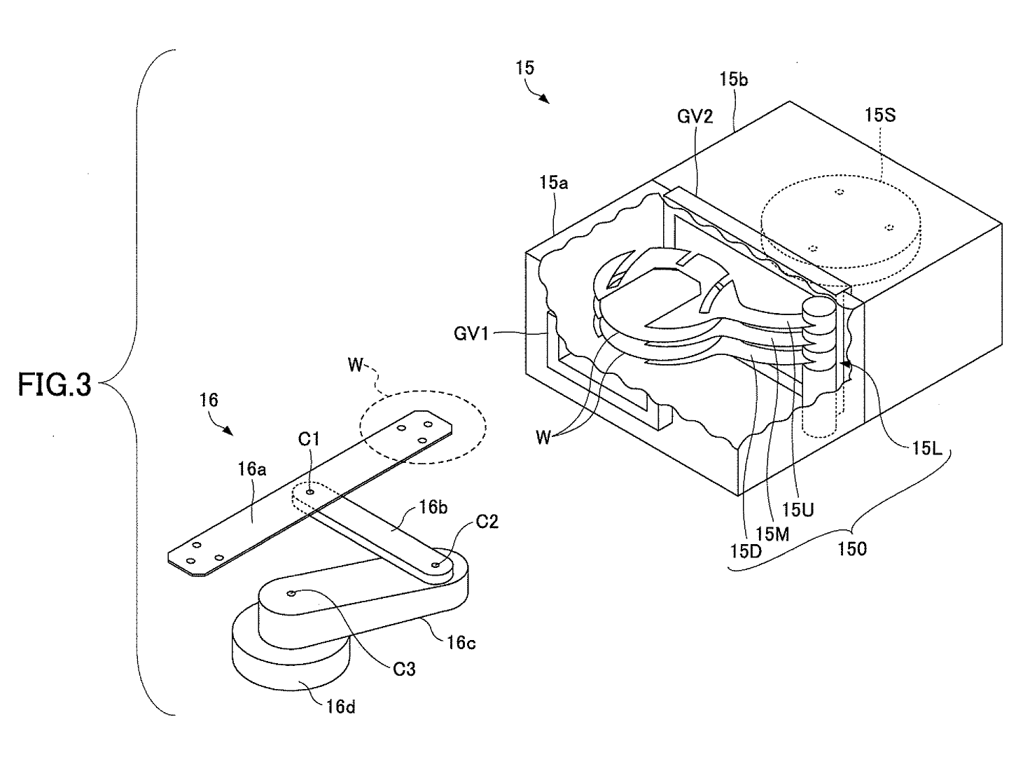

Referring to FIG. 3, the process module 15 includes a buffer chamber 15a and a process chamber 15b that are configured so that the insides thereof can be evacuated to and maintained at a reduced pressure, and a gate valve GV2 provided between the buffer chamber 15a and the process chamber 15b in order to allow the buffer chamber 15a and the process chamber 15b to be or not to be in pressure communication with each other.

The buffer chamber 15a is provided in the inside of the process chamber 15 with a substrate transfer mechanism 150 that includes plural substrate holding members 15U, 15M, 15D and a pivot shaft 15L that can independently pivot the plural substrate holding members 15U, 15M, 15D.

In addition, the process chamber 15b is provided in its inside with a susceptor 15S on which the wafer W is placed. In the process chamber 15b, a predetermined process is performed with respect to the wafer W placed on the susceptor 15S. The process may be deposition of an insulation film or an electrically conductive film, etching, thermal processing, or the like. In addition, the process may be a smoothing process performed to improve a line width roughness (LWR) of a patterned resist film, a film thickness measurement, a particle counting process, or the like. The process chamber 15b may be arbitrarily provided with a gas supplying line, a gas supplying nozzle (or showerhead), a wafer chuck, a wafer heating mechanism, electrodes for generating plasma, an optical system, or the like, depending on the process performed in the process chamber 15b.

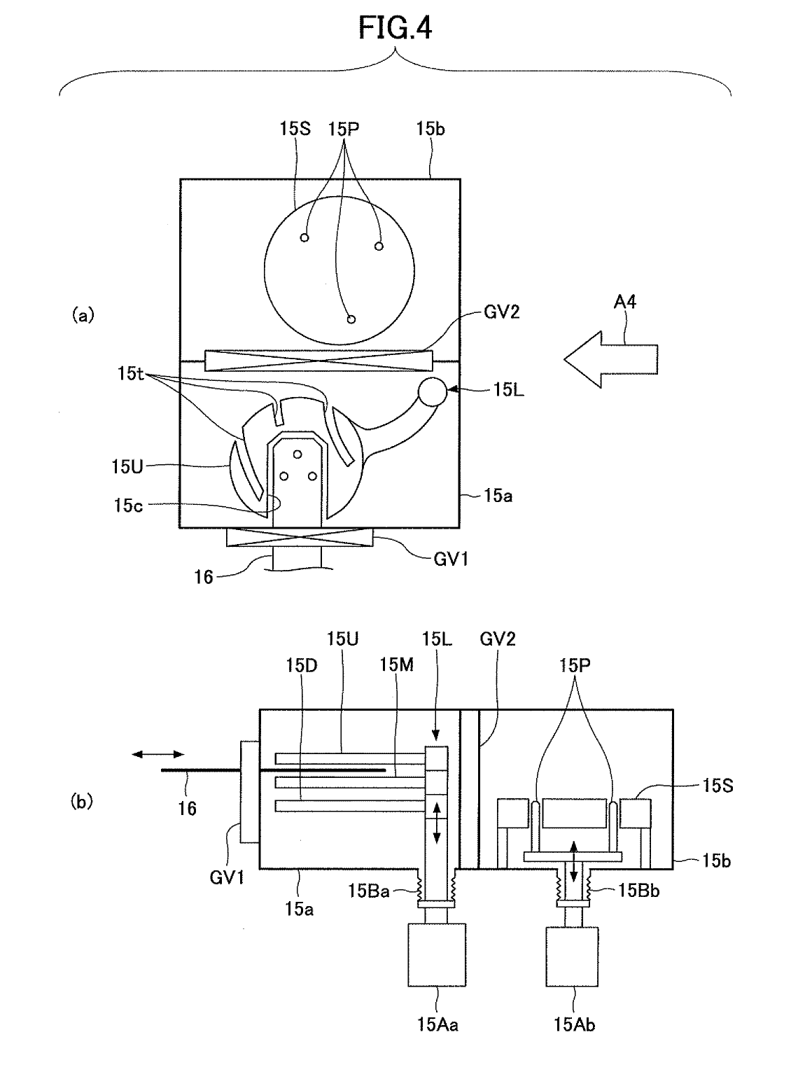

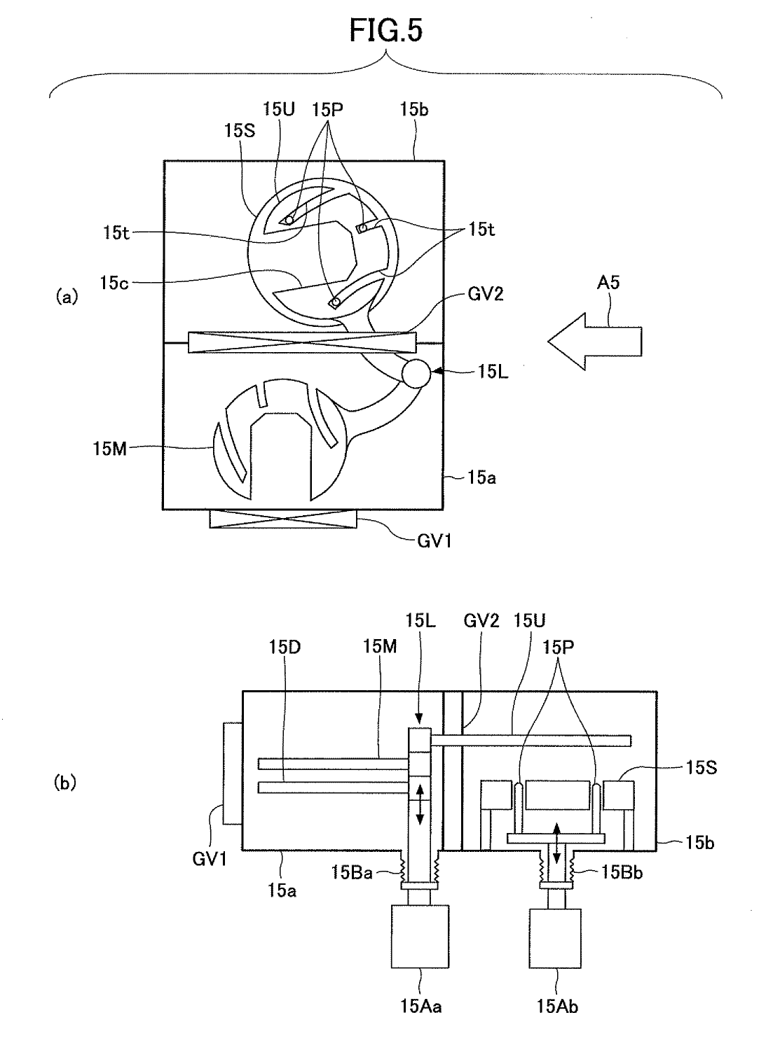

Next, the process module 15 is further explained with reference to FIGS. 4 and 5. A subsection (a) of FIG. 4 is a plan view schematically illustrating the process module 15, and a subsection (b) of FIG. 4 is a side view schematically illustrating the process module 15 seen from a direction indicated by an arrow A4 in the subsection (a) of FIG. 4. In these drawings, the transfer arm 16a (simply referred to as transfer arm 16 hereinafter) that has proceeded into the buffer chamber 15a of the process module 15 from the transport chamber 14 is also shown.

The substrate holding member 15U positioned at a home position is illustrated in the subsection (a) of FIG. 4. The substrate holding member 15U is large enough to support the wafer W subject to the process performed in the process chamber 15b, and may be made of metal such as aluminum or stainless steel. As shown, the substrate holding member 15U has a cutout portion 15c having a width wider than the width of the transfer arm 16. With this, when the transfer arm 16 proceeds into the buffer chamber 15a, the transfer arm 16 can relatively pass through the cutout portion 15c in a vertical direction, which allows the transfer arm 16 to move upward or downward. With such an upward/downward movement of the transfer arm 16, the wafer W can be transferred from the transfer arm 16 to the substrate holding member 15U and from the substrate holding member 15U to the transfer arm 16. In addition, a length (depth) of the cutout portion 15c is determined so that the transfer arm 16 that has proceeded into the cutout portion 15c can certainly transfer the wafer W to the substrate holding member 15U. As stated, the substrate holding member 15U has the cutout portion 15c that allows the transfer arm 16 (wafer holding area) to relatively pass therethrough when the substrate holding member 15U moves in the vertical direction in order to transfer the wafer W to or from the transfer arm 16.

Referring to the subsection (b) of FIG. 4, an elevation driving part 15Aa is provided below the pivot shaft 15L of the substrate holding member 15U. The elevation driving part 15Aa pivots the substrate holding member 15U and moves the substrate holding member 15U (the entire substrate transfer mechanism 150) upward or downward. A bellows 15Ba is provided between the pivot shaft 15L and (a chassis of) the buffer chamber 15a. The bellows 15Ba allows the pivot shaft 15L to move upward or downward while maintaining airtightness of the buffer chamber 15a.

The susceptor 15S arranged inside the process chamber 15b is provided with plural (three in the illustrated example) lift pins 15P that can go through the susceptor 15S in the vertical direction. The lift pins 15P are moved upward or downward by an elevation driving part 15Ab. With this, the lift pins 15P can place the wafer W onto the susceptor 15S and bring the wafer W upward from the susceptor 15S. In addition, a bellows 15Bb is provided between a rod that moves the lift pins 15P upward or downward and the (chassis of) the process chamber 15b. The bellows 15Bb allows the rod to move upward or downward while maintaining airtightness of the process chamber 15b.

Next, referring to subsections (a) and (b) of FIG. 5, the substrate holding member 15U is pivoted by the pivot shaft 15L and proceeds into the process chamber 15b through the gate valve GV2 to be positioned substantially above the susceptor 15S. In this embodiment, the substrate holding member 15U is pivoted by about 80° until reaching the position above the susceptor 15S from the home position. While a pivoting angle may be determined in accordance with a size of the wafer W to be processed in the substrate processing apparatus 10 (process module 15), the pivoting angle is preferably 90° or less, from a viewpoint of reduced dimension (footprint) of the process module 15. Incidentally, the subsection (a) of FIG. 5 is another plan view schematically illustrating the process module 15, and a subsection (b) of FIG. 4 is a side view schematically illustrating the process module 15 seen from a direction indicated by an arrow A5 in the subsection (a) of FIG. 5. As shown in the subsection (a) of FIG. 5, three slits 15t are formed in the substrate holding member 15U, which correspond to the lift pins 15P. When the substrate holding member 15U is positioned substantially above the susceptor 15S and then the lift pins 15P are raised, distal ends of the lift pins 15P go through the slits 15t to be projected above the substrate holding member 15U. In addition, the slits 15t have a curved shape. Therefore, the substrate holding member 15U can be pivoted back to the buffer chamber 15a by the pivot shaft 15L, even when the lift pins 15P are projected above the substrate holding member 15U, because the curved slits 15t allow the lift pins 15t to move along and through the curve. Namely, the substrate holding member 15U has the slits 15t of curved shapes that are formed corresponding to the lift pins 15P and allow the lift pins 15t to relatively pass therethrough when the substrate holding member 15U is pivoted by the pivot shaft 15L, even when the susceptor 15S is provided with plural lift pins 15 capable of moving upward or downward from the susceptor 15S.

Referring again to the subsection (b) of FIG. 4, substrate holding members 15M, 15D are arranged one above the other below the substrate holding member 15U. The substrate holding members 15M, 15D have the same configuration as the substrate holding member 15U, and can be independently pivoted in the same manner as the substrate holding member 15U. The substrate holding members 15U, 15M, 15D can be pivoted, for example, by motors provided corresponding to the substrate holding members 15U, 15M, 15D within the elevation driving part 15Aa and a ternary coaxial shaft having an outer tube, a middle tube arranged inside the outer tube, and an inner rod that couple the motors with the corresponding substrate holding members 15U, 15M, 15D.

Referring again to FIG. 1, the substrate processing apparatus 10 is provided with a control part that controls constituent components or members of the substrate processing apparatus 10, in order to execute various processes in the substrate processing apparatus 10. The control part 17 includes a central processing unit, and operates in accordance with a program that includes a group of instructions that make the substrate processing apparatus 10 execute a substrate transfer method described later. The program is stored in a computer readable storage medium 17a, and loaded into a memory device 17b through an input/output (I/O) device (not shown) corresponding to the computer readable storage medium 17a. The computer readable storage medium 17a may be a flexible disk, a solid state memory, or a hard disk, for example. In addition, the program may be downloaded into the memory device 17b from a predetermined communication line rather than the computer readable storage medium 17a.

Advantages or effects of the process module 15 and the substrate processing apparatus 10 including the process module 15 are easily understood from the following explanation about a substrate transfer method according to an embodiment of the present invention.

### Second Embodiment

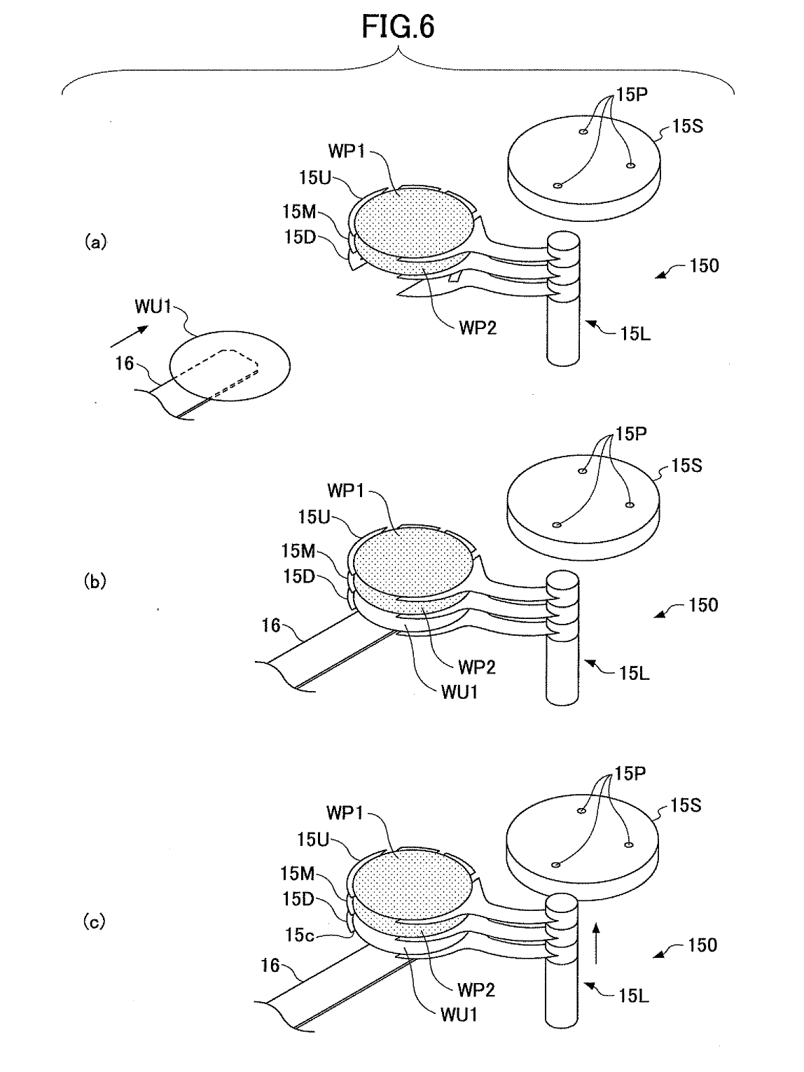

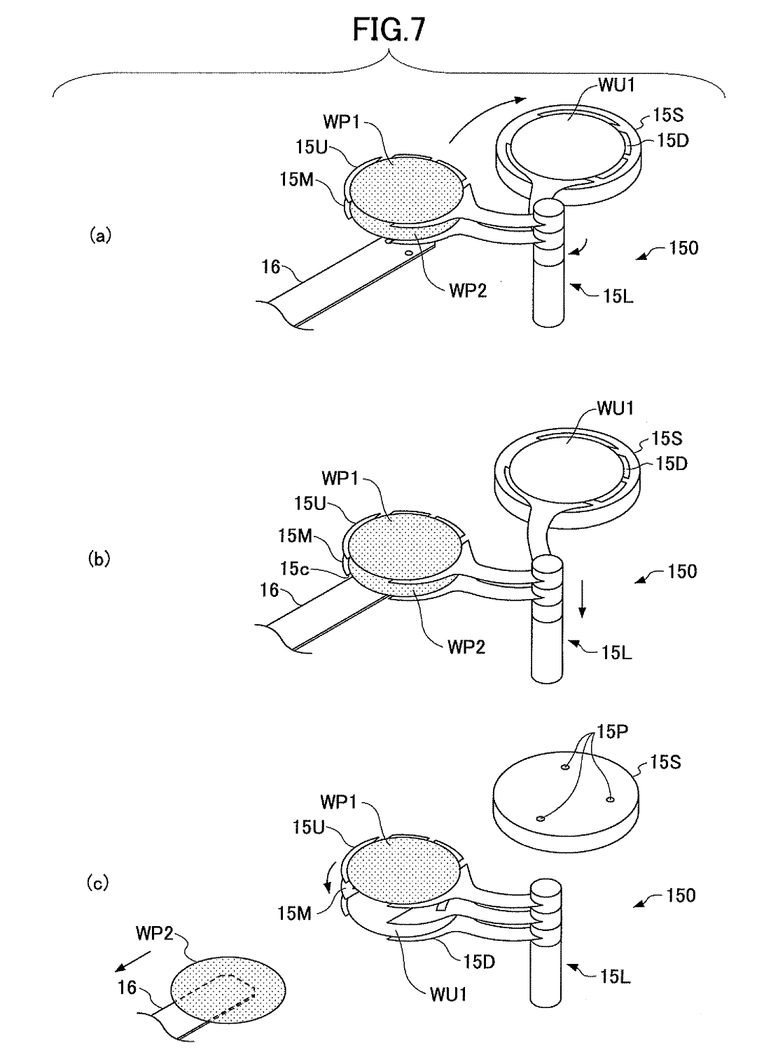

A substrate transfer method according to a second embodiment of the present invention is explained with reference to FIGS. 6 and 7. In the following explanation, the substrate transfer method is carried out in the substrate processing apparatus 10. In FIGS. 6 and 7, the gate valves GV1, GV2, (the chassis of) the buffer chamber 15a, and (the chassis of) the process chamber 15b that are shown in FIG. 3 are omitted for the sake of explanatory convenience, but a positional relationship of the substrate holding members 15U, 15M, 15D, (the distal end of) the transfer arm 16, and the susceptor is mainly illustrated.

Referring to a subsection (a) of FIG. 6, the buffer chamber 15a (see FIG. 3) is provided in its inside with the substrate transfer mechanism 150 having the substrate holding members 15U, 15M, 15D, which are positioned in their home positions. In addition, the two substrate holding members 15U, 15M from above hold corresponding wafers WP1, WP2 that have been processed in the process chamber 15b (see FIG. 3), (referred to as processed wafers WP1, WP2), and the lowermost substrate holding member 15D holds no wafer. Moreover, there is no wafer on the susceptor 15S in the process chamber 15b (see FIG. 3), and the transfer arm 16 in the transport chamber 14 (see FIG. 3) holds at one end a wafer WU1 that is to be processed in the process chamber 15b (referred to as an unprocessed wafer WU1).

First, the substrate transfer mechanism 150 is moved upward or downward in order to adjust a vertical position of the substrate transfer mechanism 150 so that the transfer arm 16 can proceed into a space between the substrate holding members 15M and 15D. Second, when the gate valve GV1 (see FIG. 3) between the buffer chamber 15a and the transport chamber 14 is opened, the transfer arm 16 proceeds into the buffer chamber 15a and holds the unprocessed wafer WU1 between the substrate holding members 15M and 15D, as shown in a subsection (b) of FIG. 6. Next, when the substrate transfer mechanism 150 is moved upward, the transfer arm 16 relatively passes through the cutout part 15c of the substrate holding member 15D from above to below, and thus the unprocessed wafer WU1 is received by the substrate holding member 15D, as shown in a subsection (c) of FIG. 6. After the unprocessed wafer WU1 is received by the substrate holding member 15D, the transfer arm 16 does not return to the transport chamber 14 but stays in the same position in the buffer chamber 15a.

Next, when the gate valve GV2 between the buffer chamber 15a and the process chamber 15b (see FIG. 3) is opened, the substrate holding member 15D holding the unprocessed wafer WU1 is pivoted into the process chamber 15b by the pivot shaft 15L, and holds the unprocessed wafer WU1 above the susceptor 15S in the process chamber 15b, as shown in a subsection (a) of FIG. 7. While the pivot angle of the substrate holding member 15D is about 80°, the pivot angle may be determined in accordance with the size of the unprocessed wafer WU1 (processed wafers WP1, WP2), as explained in the first embodiment. The same is true for the substrate holding members 15U, 15M. When the substrate holding member 15D is being pivoted or after the substrate holding member 15D is pivoted, the pivot shaft 15L is moved downward, the transfer arm 16 relatively passes through the cutout part 15c of the substrate holding member 15M from below to above, and thus the processed wafer WP2 is received by the transfer arm 16, as shown in a subsection (b) of FIG. 7. Then, the transfer arm 16 transfers the processed wafer WP2 out from the buffer chamber 15a to the transport chamber 14, and the substrate holding member 15D is returned to the home position while holding the unprocessed wafer WU1. After a series of the above procedures, the substrate holding member 15U holds the processed wafer WP1; the substrate holding member 15M holds no wafer; and the substrate holding member 15D holds the unprocessed wafer WU1, inside the buffer chamber 15a (see FIG. 3), as shown in a subsection (c) of FIG. 7.

Next, when the transfer arm 16 is rotated by 180° around the rotation axis C1 (see FIG. 2), another unprocessed wafer (called an unprocessed wafer WU2, for the sake of explanatory convenience, although not shown) is moved by the other end of the transfer arm 16 to a position in front of the buffer chamber 15a. Then, the substrate transfer is continued in the following manner. Namely, the transfer arm 16 proceeds into the buffer chamber 15a, and holds the unprocessed wafer WU2 between the substrate holding members 15U and 15M. Next, when the substrate transfer mechanism 150 is moved upward, the unprocessed wafer WU2 is transferred from the transfer arm 16 to the substrate holding member 15M. After the unprocessed wafer WU2 is received by the substrate holding member 15M, the transfer arm 16 does not return to the transport chamber 14 but stays in the same position in the buffer chamber 15a.

Then, when the substrate holding member 15M holding the unprocessed wafer WU2 is pivoted by the pivot shaft 15L of the substrate transfer mechanism 150, and holds the unprocessed wafer WU2 above the susceptor 15S in the process chamber 15b. When the substrate holding member 15M is being pivoted or after the substrate holding member 15M is pivoted, the substrate transfer mechanism 150 is moved downward, the processed wafer WP1 held by the substrate holding member 15U is received by the transfer arm 16. Next, the transfer arm 16 transfers the processed wafer WP1 out from the buffer chamber 15a, and the substrate holding member 15M holding the unprocessed wafer WU2 is returned to the home position. After this series of the above procedures, the substrate holding member 15U holds no wafer; the substrate holding member 15M holds the unprocessed wafer WU2; and the substrate holding member 15D holds the unprocessed wafer WU1, inside the buffer chamber 15a (see FIG. 3).

Subsequently, the unprocessed wafers WU1, WU2 are transferred from the buffer chamber 15a to the process chamber 15b in turn, and each of the unprocessed wafers WU1, WU2 goes through a predetermined process in the process chamber 15b. Specifically, the substrate holding member 15M is pivoted by the pivot shaft 15L and holds the unprocessed wafer WU2 above the susceptor 15S in the process chamber 15b. Next, the lift pins 15P of the susceptor 15S are moved upward and go through the corresponding slits 15t to move the unprocessed wafer WU2 upward. Namely, the unprocessed wafer WU2 is received by the lift pins 15P. Then, the substrate holding member 15M is pivoted back to the home position. The lift pins 15P are moved downward, and thus the unprocessed wafer WU2 is placed on the susceptor 15S. After the gate valve GV2 is closed, so that the process chamber 15b is hermetically sealed, the predetermined process is performed with respect to the unprocessed wafer WU2 on the susceptor 15S. In the following, the wafer WU2 that has gone through the predetermined process is called a processed wafer WP3, for the sake of explanatory convenience, although not shown.

After the process is completed, the lift pins 15P are moved upward to bring the wafer WP3 from the susceptor 15S. Then, when the gate valve GV2 is opened, the substrate holding member 15M is pivoted by the pivot shaft 15L and positioned between the wafer WP3 and the susceptor 15S while allowing the lift pins 15P to relatively pass through the corresponding silts 15t of the substrate holding member 15M. Next, when the lift pins 15P are moved downward, the wafer WP3 is received by the substrate holding member 15M. Subsequently, the substrate holding member 15M holding the wafer WP3 is returned to the home position and at the same time the substrate holding member 15D holding the wafer WU1 is pivoted and positioned above the susceptor 15S, thereby holding the wafer WU1 above the susceptor 15S. When the lift pins 15P are moved upward, the wafer WU1 is transferred from the substrate holding member 15D to the lift pins 15P. Then, when the substrate holding member 15D is returned to the home position and the lift pins 15P are moved downward, the wafer WU1 is placed on the susceptor 15S. Next, the gate valve GV2 is closed, the wafer WU1 goes through the process. The wafer WU1 that has gone through the process is called as a wafer WP4, for the sake of explanatory convenience, although not shown.

After the process is completed, the wafer WP4 is moved upward by the lift pins 15P, and the height of the substrate transfer mechanism 150 is adjusted so that the substrate holding member 15U, which holds no wafer, can be positioned between the wafer WP4 and the susceptor 15S. Then, the gate valve GV2 is opened, and the substrate holding member 15U is pivoted and positioned between the wafer WP4 and the susceptor 15S. When the lift pins 15P are moved downward, the wafer WP4 is transferred from the lift pins 15P to the substrate holding member 15U. Finally, the substrate holding member 15U holding the wafer WP4 is returned to the home position, and the gate valve GV2 is closed. The situation at this time is illustrated in the subsection (a) of FIG. 6. Subsequently, the same procedures are repeated until all the wafers to be processed go through the process.

As stated above, the unprocessed wafer WU1 is transferred from the transfer arm 16 to the substrate holding member 15D, when the substrate holding members 15U, 15M, 15D are positioned at their home positions. While the wafer WU1 is moved to the position above the susceptor 15S by the substrate holding member 15D, the transfer arm 16 stays in the home positions of the substrate holding members 15U, 15M, 15D, receives the processed wafer WP2 from the substrate holding member 15M, and then leaves the home positions (the buffer chamber 15a) to the transport chamber 14. Therefore, the transfer arm 16 can transfer the unprocessed wafer WU1 into the buffer chamber 15a, and transfer the processed wafer WP2 out from the buffer chamber 15a while the transfer arm 16 reciprocates only once between the buffer chamber 15a and the transport chamber 14. Namely, the transfer arm 16 is not required to reciprocate twice between the buffer chamber 15a and the transport chamber 14. Accordingly, the time required to transfer a wafer into and out from the buffer chamber 15a may be reduced.

Such an advantage is easily understood when compared to a conventional case where a wafer transfer arm has to reciprocate twice between a first process chamber and a transport chamber. Namely, in a conventional manner, the wafer transfer arm proceeds into a first process chamber to take a processed wafer out from the first process chamber (first reciprocating movement), transfers the processed wafer to a second process chamber, takes an unprocessed wafer from a load lock chamber, transfers an unprocessed wafer into the first wafer and then goes back to the transport chamber (second reciprocating movement).

Moreover, transferring the processed wafer WP3 out from and transferring the unprocessed wafer WU1 into the process chamber 15b are carried out at the same time by pivoting the substrate holding member 15M holding the wafer WP3 moving from the process chamber 15b to the buffer chamber 15a and the substrate holding member 15D holding the wafer WU1 moving from the buffer chamber 15a to the process chamber 15b at the same time. Therefore, the wafer transfer time can be reduced.

In addition, because the main transfer apparatus 16 (transfer arm 16), which is relatively large, and the substrate transfer mechanism 150, which is relatively small and can turn in a relatively small radius, move in concert with each other, the wafer W can be transferred in a quick and efficient manner.

### Third Embodiment

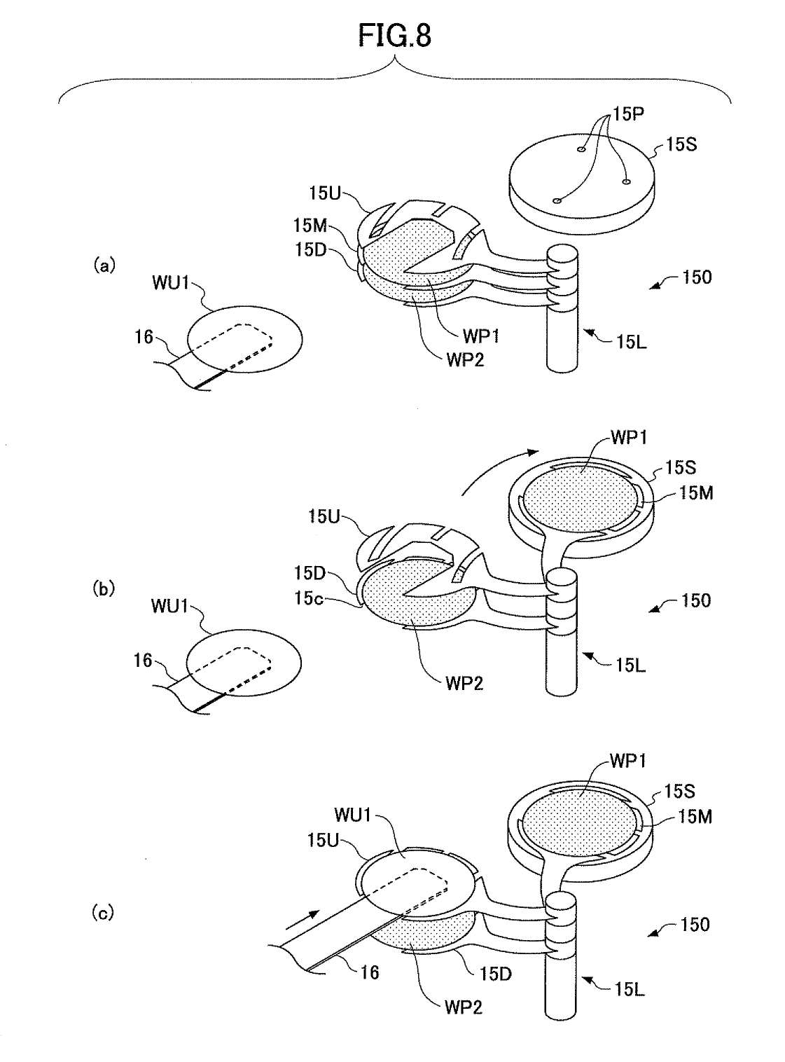

Next, a substrate transfer method according to a third embodiment of the present invention is explained with reference to FIGS. 8 through 12. In the following explanation, the substrate transfer method is carried out in the substrate processing apparatus 10. Even in FIGS. 8 through 12, the gate valves GV1, GV2, (the chassis of) the buffer chamber 15a, and (the chassis of) the process chamber 15b that are shown in FIG. 3 are omitted for the sake of explanatory convenience, but a positional relationship of the substrate holding members 15U, 15M, 15D, (the distal end of) the transfer arm 16, and the susceptor is mainly illustrated.

Referring to a subsection (a) of FIG. 8, the buffer chamber 15a (see FIG. 3) is provided in its inside with the substrate transfer mechanism 150 having the substrate holding members 15U, 15M, 15D, which are positioned in their home positions. In addition, the two substrate holding members 15M, 15D hold corresponding wafers WP1, WP2 that have been processed in the process chamber 15b (see FIG. 3), (referred to as processed wafers WP1, WP2), and the uppermost substrate holding member 15U holds no wafer. Moreover, there is no wafer on the susceptor 15S in the process chamber 15b (see FIG. 3), and the transfer arm 16 in the transport chamber 14 (see FIG. 3) holds at one end a wafer WU1 that is to be processed in the process chamber 15b (referred to as an unprocessed wafer WU1).

First, the substrate transfer mechanism 150 is moved upward or downward in order to adjust a vertical position of the substrate transfer mechanism 150 so that the transfer arm 16 can proceed into a position above the substrate holding member 15U. Second, the middle substrate holding member 15M is pivoted by the pivot shaft 15L, thereby temporarily holding the processed wafer WP1 above the susceptor 15S, as shown in a subsection (b) of FIG. 8. While the pivot angle of the substrate holding member 15M is about 80°, the pivot angle may be determined in accordance with the size of the unprocessed wafer WP1, as explained in the first embodiment. The same is true for the substrate holding members 15U, 15D.

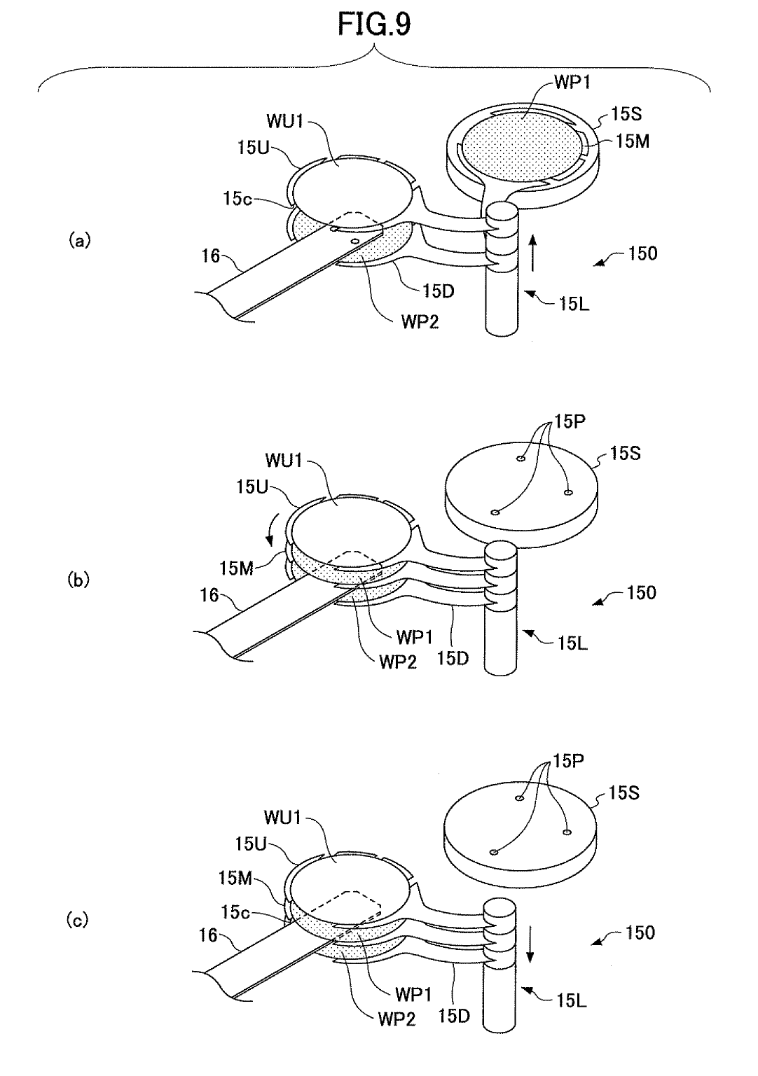

Next, when the gate valve GV1 between the buffer chamber 15a and the transport chamber 14 is opened, the transfer arm 16 proceeds into the buffer chamber 15a and holds an unprocessed wafer WU1 above the substrate holding member 15U, as shown in a subsection (c) of FIG. 8. When the substrate transfer mechanism 150 is moved upward 150, the transfer arm 16 relatively passes through the cutout part 15c of the substrate holding member 15U from above to below, and thus the unprocessed wafer WU1 is transferred from the transfer arm 16 to the substrate holding member 15U, as shown in a subsection (a) of FIG. 9. After the wafer WU1 is received by the substrate holding member 15U, the transfer arm 16 does not return to the transport chamber 14 but stays in the same position in the buffer chamber 15a.

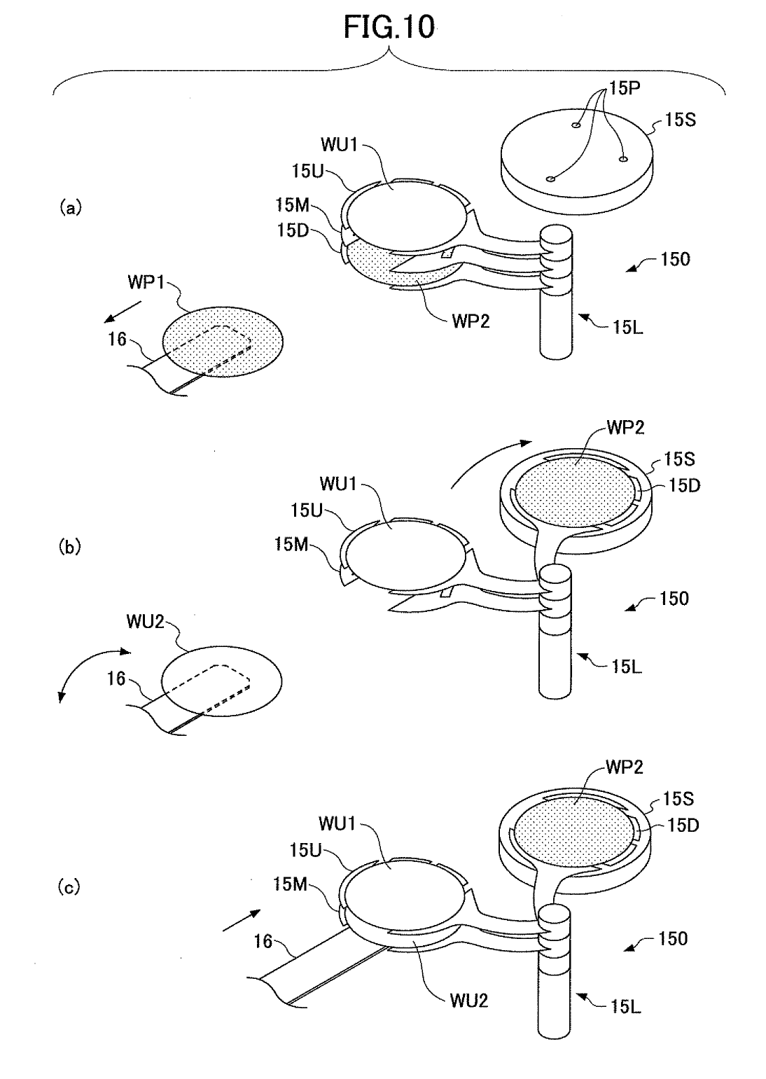

Next, the substrate holding member 15M holding the processed wafer WP1 above the susceptor 15S is pivoted back to the home position by the pivot shaft 15L, as shown in a subsection (b) of FIG. 9. At this time, the vertical position of the substrate transfer mechanism 150 is adjusted so that the substrate holding member 15M can be positioned between the substrate holding member 15U and the transport arm 16. After the substrate holding member 15M is returned to the home position, the pivot shaft 15L (substrate transfer mechanism 150) is moved downward, which allows the transfer arm 16 to relatively pass through the cutout part 15c of the substrate holding member 15M, and thus the processed wafer WP1 is transferred from the substrate holding member 15M to the transfer arm 16, as shown in a subsection (c) of FIG. 9. Subsequently, the transfer arm 16 transfers the processed wafer WP1 out from the buffer chamber 15a to the transport chamber 14. After a series of the above procedures, the substrate holding member 15U holds the unprocessed wafer WU1; the substrate holding member 15M holds no wafer; and the substrate holding member 15D holds the unprocessed wafer WP2, inside the buffer chamber 15a (see FIG. 3), as shown in a subsection (a) of FIG. 10.

Next, when the transfer arm 16 is rotated by 180° around the rotation axis C1 (see FIG. 2), another unprocessed wafer WU2 is moved by the other end of the transfer arm 16 to a position in front of the buffer chamber 15a. At this time, the lowermost substrate holding member 15D is pivoted, thereby temporarily holding the processed wafer WP2 above the susceptor 15S, as shown in a subsection (b) of FIG. 10.

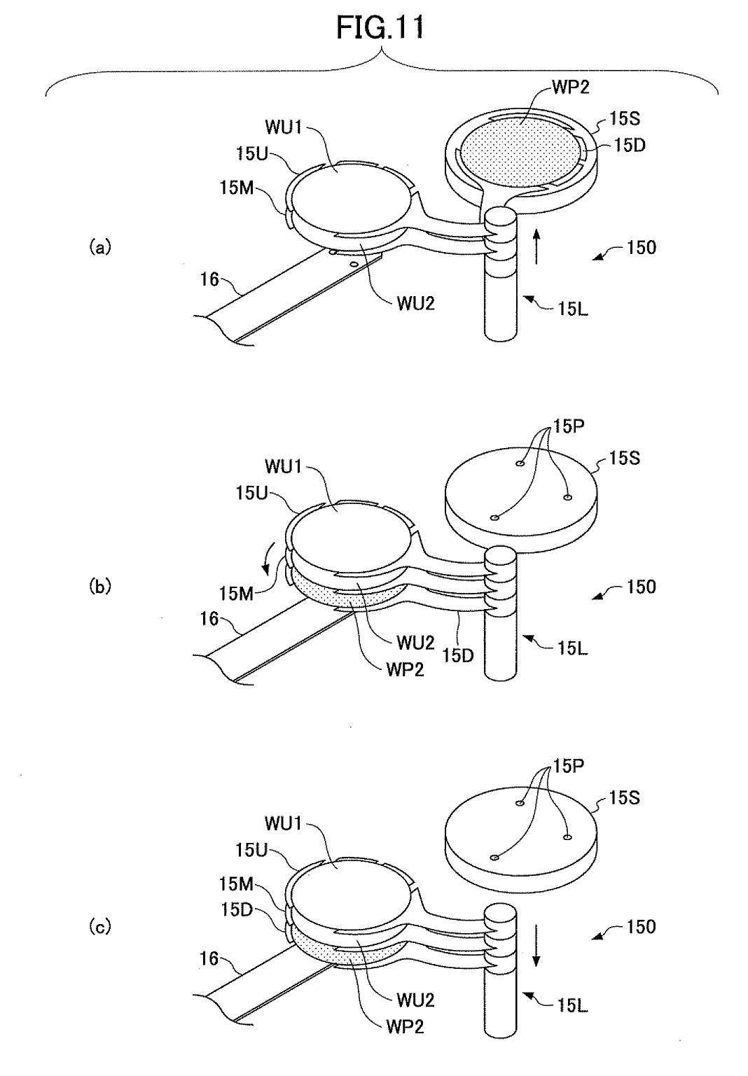

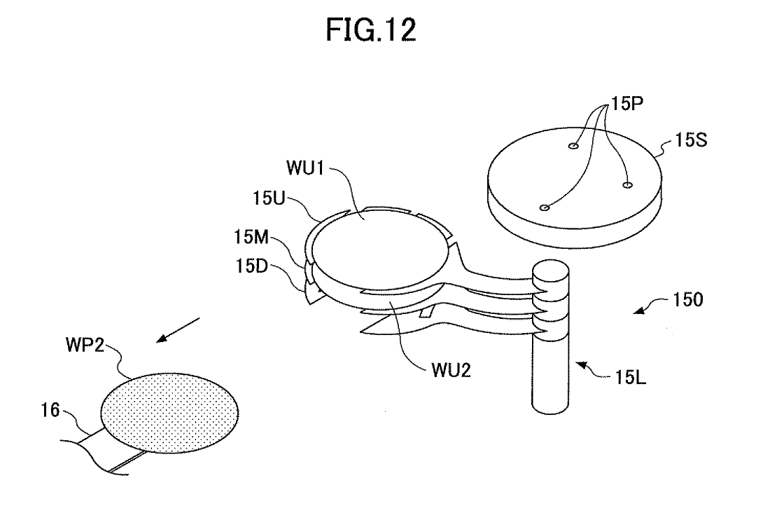

Next, the transfer arm 16 holding the unprocessed wafer WU2 proceeds into a space between the substrate holding members 15U and 15M, and holds the wafer WU2 between the substrate holding members 15U and 15M, as shown in a subsection (c) of FIG. 10. At this time, the vertical position of the substrate transfer mechanism 150 is adjusted so that the transfer arm 16 can proceed into the space between the substrate holding members 15U and 15M. Then, when the pivot shaft 15L (substrate transfer mechanism 150) is moved upward, the unprocessed wafer WU2 is transferred from the transfer arm 16 to the substrate holding member 15M, as shown in a subsection (a) of FIG. 11. At this time, the vertical position of the pivot shaft 15L (substrate transfer mechanism 150) is adjusted so that the substrate holding member 15D holding the processed wafer WP2 above the susceptor 15S can be returned above the transfer arm 16. Then, the substrate holding member 15D is pivoted back to the home position by the pivot shaft 15L, as shown in a subsection (b) of FIG. 11. Next, when the pivot shaft 15L is moved downward, the processed wafer WP2 is transferred from the substrate holding member 15D to the transfer arm 16, as shown in a subsection (c) of FIG. 11. Subsequently, the transfer arm 16 transfers the processed wafer WP2 from the buffer chamber 15a to the transport chamber 14 (see FIG. 3). After this series of the procedures so far, the substrate holding member 15U holds the unprocessed wafer WU1; the substrate holding member 15M holds the unprocessed wafer WU2; and the substrate holding member 15D holds no wafer, inside the buffer chamber 15a (see FIG. 3), as shown in FIG. 12.

Next, the unprocessed wafers WU1, WU2 are transferred to the process chamber 15b (see FIG. 3), and go through a predetermined process in the process chamber 15b, in turn. Then, the same procedures are repeated until all the wafers to be processed are processed in the same manner.

According to this embodiment, the transfer arm 16 can transfer the unprocessed wafer WU1 to the uppermost substrate holding member 15U, receive the processed wafer WP1 from the middle substrate holding member 15M, and return to the transport chamber 14. In addition, the transfer arm 16 can transfer the unprocessed wafer WU2 to the middle substrate holding member 15M, receive the processed wafer WP2 from the lowermost substrate holding member 15D, and return to the transport chamber 14. Therefore, the transfer arm 16 can transport a wafer in and out without reciprocating twice between the transport chamber 14 and the buffer chamber 15a, thereby reducing the wafer transfer time.

In addition, this embodiment can also provide the same advantage provided by the relatively large main transfer apparatus 16 (transfer arm 16) and the relatively small substrate transfer mechanism 150 moving in concert with each other.

### Fourth Embodiment

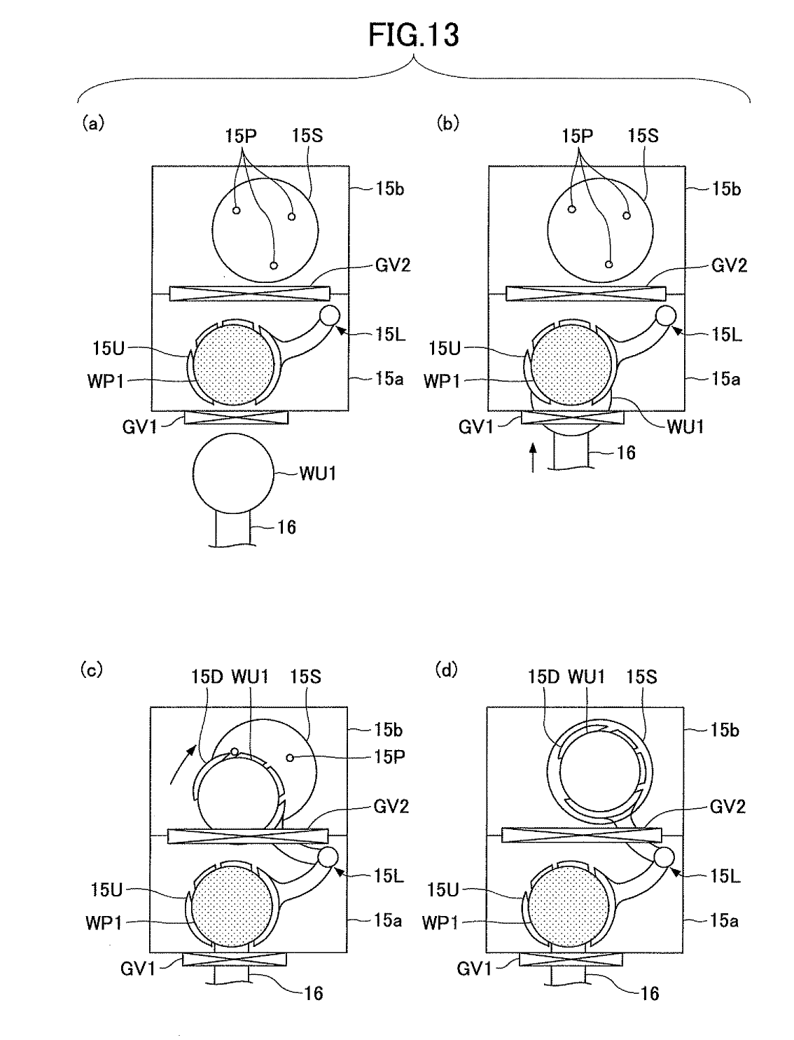

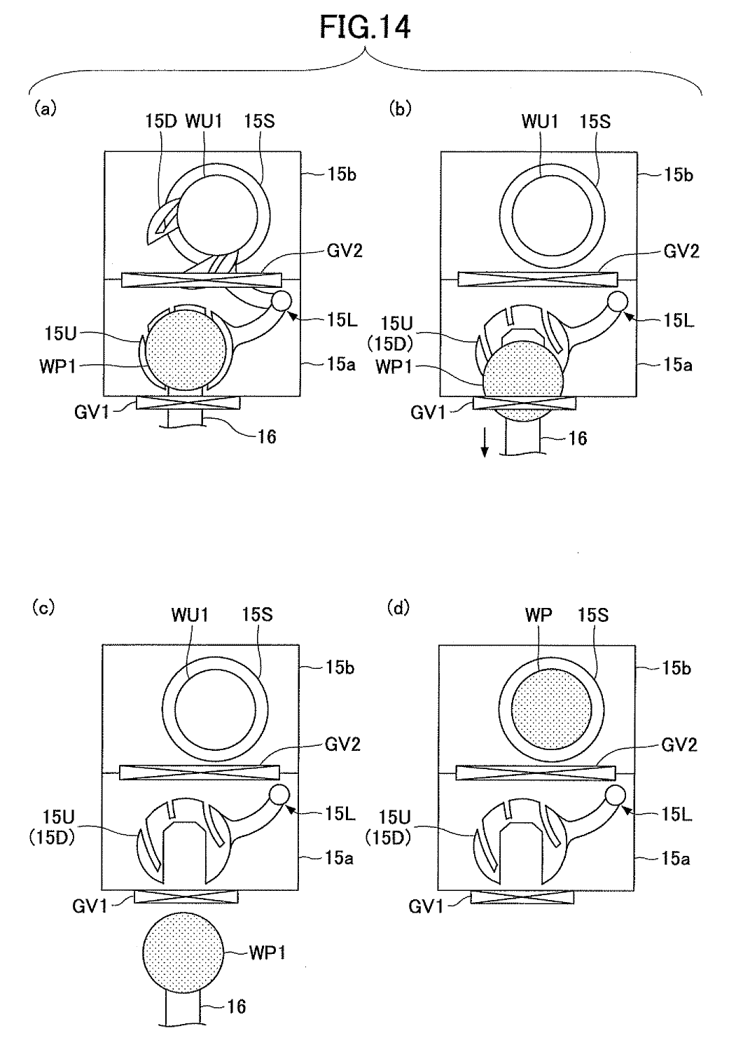

A substrate transfer method according to a fourth embodiment of the present invention is explained with reference to FIGS. 13 through 14, which are plan views illustrating the buffer chamber 15a and the process chamber 15b. In addition, the process module 15 used to carry out the substrate transfer method of this embodiment is provided with a substrate transfer mechanism having two substrate holding members 15U, 15D in the buffer chamber 15a.

Referring to a subsection (a) of FIG. 13, the substrate holding member 15U holds the processed wafer WP1 that has been processed in the process chamber 15b in the buffer chamber 15a. The substrate holding member 15D arranged below the substrate holding member 15U holds no wafer. In addition, there is no wafer on the susceptor 15S in the process chamber 15b, and the transfer arm 16 in the transport chamber 14 holds at one end a wafer WU1 to be processed in the process chamber 15b.

First, a vertical position of the substrate transfer mechanism is adjusted by the pivot shaft 15L so that the transfer arm 16 can proceed into a space between the substrate holding members 15U, 15D. Next, when the gate valve GV1 is opened, the transfer arm 16 proceeds into the buffer chamber 15a, as shown in a subsection (b) of FIG. 13, and holds the unprocessed wafer WU1 between the substrate holding members 15U and 15D.

When the pivot shaft 15L is moved upward, the substrate holding member 15D receives the unprocessed wafer WU1 from the transfer arm 16. Then, when the gate valve GV2 is opened, the substrate holding member 15D is pivoted by the pivot shaft 15L, as shown in a subsection (c) of FIG. 13 and holds the unprocessed wafer WU1 above the susceptor 15S. The pivot angle of the substrate holding member 15D is about 80°. Next, the lift pins 15P in the susceptor 15S are moved upward and pass through the corresponding slits 15t (see FIG. 3) of the substrate holding member 15D, thereby receiving the unprocessed wafer WU1 from the substrate holding member 15D. In addition, the processed wafer WP1 held by the substrate holding member 15U is transferred to the transfer arm 16 by moving the pivot shaft 15L downward, as shown in a subsection (d) of FIG. 13.

Next, the substrate holding member 15D is pivoted by the pivot shaft 15L without holding any wafer, as shown in a subsection (a) of FIG. 14, and positioned at the home position. Then, the gate valve GV2 is closed. In the process chamber 15b, the lift pins 15P are moved downward, and thus the unprocessed wafer WU1 is placed on the susceptor 15S. On the other hand, the processed wafer WP1 is transferred out from the buffer chamber 15a to the transport chamber 14 by the transfer arm 16, as shown in a subsection (b) of FIG. 14. Then, the processed wafer WP1 is transferred to another process chamber or the load lock chamber 13, and the unprocessed wafer WU1 on the susceptor 15S in the process chamber 15b goes through a predetermined process (a subsection (c) of FIG. 14).

After the process is completed, the processed wafer WP (a subsection (d) of FIG. 14), which is the wafer WU1 after the process, is transferred out to the buffer chamber 15a by the lift pins 15P and the substrate holding member 15U, and held at the home position of the substrate holding member 15U. On the other hand, the transfer arm 16 holds another unprocessed wafer, and stays in front of the buffer chamber 15a. Namely, the situation at this time is illustrated in the subsection (a) of FIG. 13. Subsequently, the above procedures are repeated until all the wafers to be processed are processed.

According to the fourth embodiment of the present invention, the transfer arm 16 transfers the unprocessed wafer WU1 to the substrate holding member 15D, receives the processed wafer WP1 from the substrate holding member 15U, and returns to the transport chamber 14. Therefore, the transfer arm 16 can transfer wafers into and out from the buffer chamber 15a without reciprocating twice between the transport chamber 14 and the buffer chamber 15a, thereby reducing the wafer transfer time.

In addition, because the substrate holding member 15D returns to the home position after placing the unprocessed wafer WU1, which the substrate holding member 15D has received from the transfer arm 16, on the susceptor 15S, the substrate holding member 15D does not have to reciprocate between the home position and the position above the susceptor 15S while keeping the unprocessed wafer WU1. Therefore, the number of reciprocating movements of the substrate holding member 15D can be reduced, thereby contributing to further reduction of the wafer transfer time. Moreover, the transfer arm 16 can transfer the processed wafer WP1 received from the substrate holding member 15U to another process module 15, take another unprocessed wafer from, for example, the load lock chamber 13, and hold the unprocessed wafer in front of the buffer chamber 15a, during a period of time when the wafer WU1 on the susceptor 15S in the process chamber 15b goes through the predetermined process and is taken out from the process chamber 15b by the substrate holding member 15D. Therefore, the transfer arm 16 does not have to stand still for a long time, thereby contributing further to the reduction of the wafer transfer time. In this case, the main transfer apparatus 16 may have only one wafer holding area.

### Fifth Embodiment

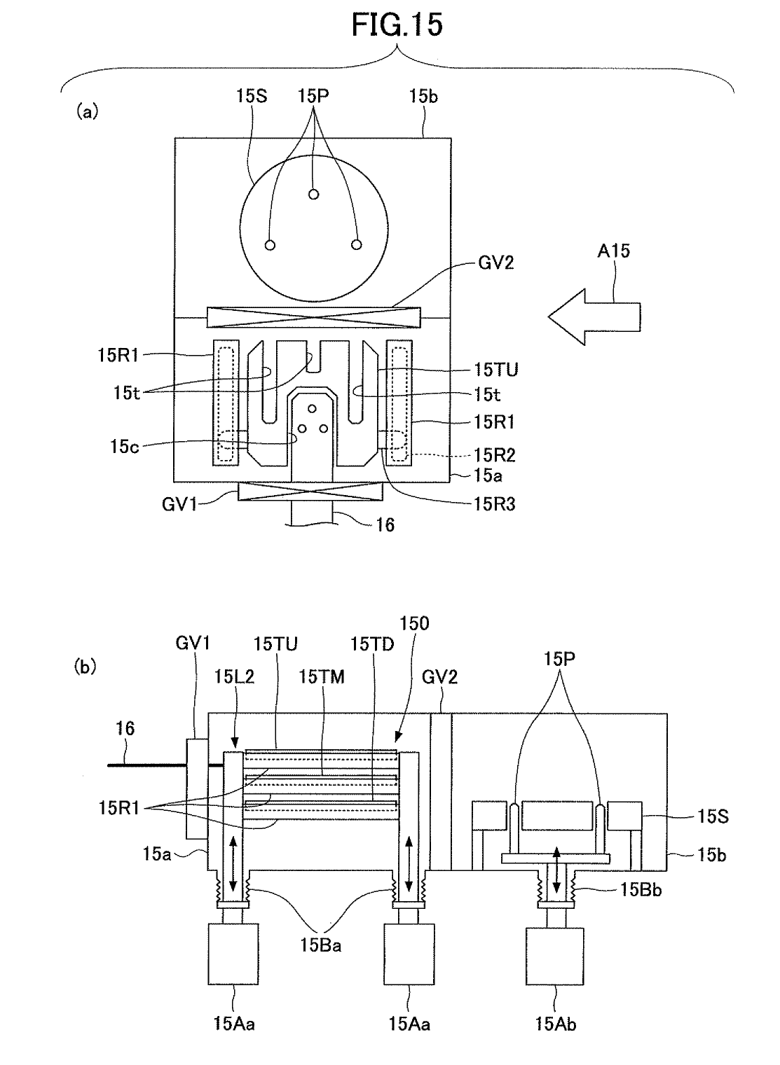

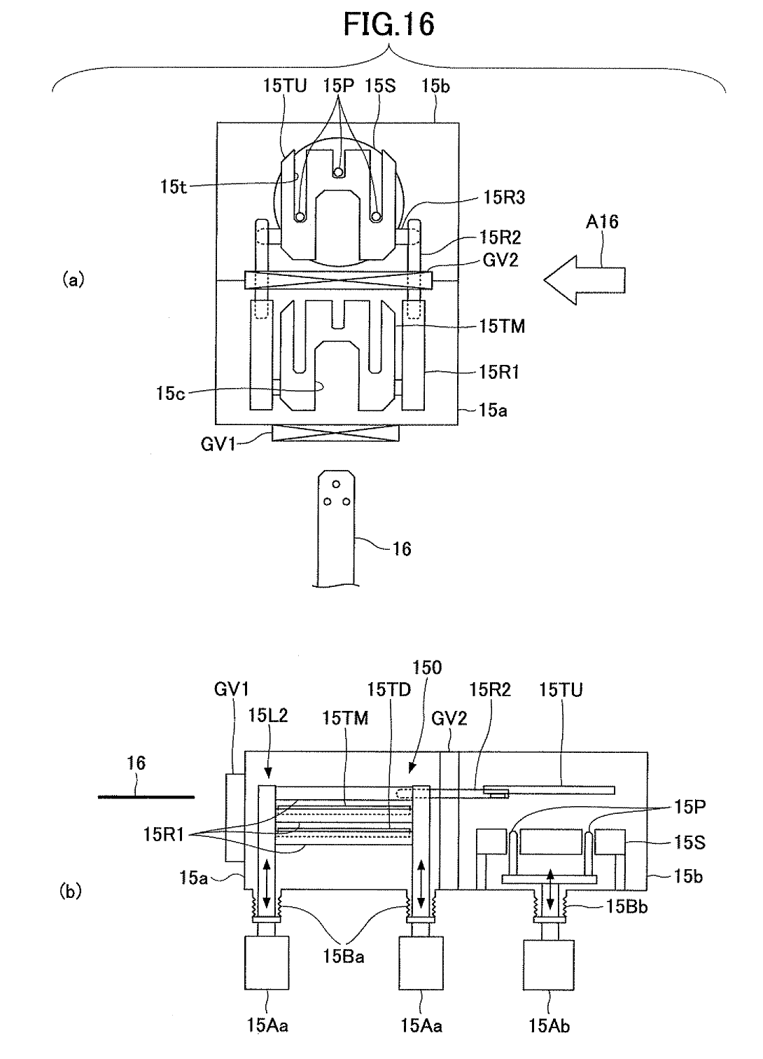

A modified example of the process module 15 is explained as a fifth embodiment of the present invention with reference to FIGS. 15 through 16.

A subsection (a) of FIG. 15 is a plan view of the process module according to the modified example, where a substrate holding member 15TU is positioned in a home position. As shown, the substrate holding member 15TU has the cutout part 15c having a width greater than the width of the transfer arm 16, in the same manner as the substrate holding member 15U shown in the subsection (a) of FIG. 3 and the like. With the cutout part 15c, the transfer arm 16 can be moved upward and downward in the buffer chamber 15a. The substrate holding member 15TU is provided with three slits 15t. The slits 15t of the substrate holding member 15TU have linear shapes because the substrate holding member 15TU linearly reciprocates.

The substrate holding member 15TU is supported from both sides thereof by two horizontal driving parts 15R1, which include linear driving mechanisms 15R2 and linear driving mechanisms 15R3 that serve also as supporting parts that the support the substrate holding member 15TU. When the linear driving mechanisms 15R2, 15R3 slide, the substrate holding member 15TU can be linearly moved, thereby being positioned at the home position in the buffer chamber 15a and the position above the susceptor 15S in the process chamber 15b.

Referring to a subsection (b) of FIG. 15, which is a side view of the process module 15 seen from a direction of an arrow A15 shown in the subsection (a) of FIG. 15, substrate holding members 15TM, 15TD are arranged below the substrate holding member 15TU. The substrate holding members 15TM, 15TD have the same configuration, and are supported by corresponding horizontal driving parts 15R1, thereby being positioned at the home position in the buffer chamber 15a and the position above the susceptor 15S in the process chamber 15b, in the same manner as the substrate holding member 15TU. The three horizontal driving parts 15R1 corresponding to the substrate holding members 15TU, 15TM, 15TD are supported by rods 15L2 whose bottom portions are coupled to elevation driving parts 15Aa, thereby moving the substrate holding members 15TU, 15TM, 15TD upward and downward.

A subsection (a) of FIG. 16 is another plan view illustrating the process module 15 according to the modified example, and a subsection (b) of FIG. 16 is another side view of the process module 15 according to the modified example, seen from a direction of an arrow A16 shown in the subsection (a) of FIG. 16. In these drawings, the gate valve GV2 is opened; and the substrate holding member 15TU proceeds into the process chamber 15b and is positioned at a position above the susceptor 15S. As shown, the linear driving mechanism 15R2 extends into the process chamber 15b and the linear driving mechanism 15R3 slides with respect to the linear driving mechanism 15R2, so that the substrate holding member 15TU is held above the susceptor 15S. As shown in the subsection (a) of FIG. 16, the lift pins 15P in the susceptor 15S are arranged corresponding to the slits 15t of the substrate holding member 15TU (15TM, 15TD) held above the susceptor 15S. Therefore, distal ends of the lift pins 15P can be projected above the substrate holding member 15TU (15TM, 15TD) through the corresponding slits 15t. In addition, the substrate holding member 15TU can be horizontally moved by the linear driving mechanisms 15R2, 15R3 even when the lift pins 15P are projected upward from the susceptor 15S. Namely, with such a configuration, a wafer can be transferred between the substrate holding member 15TU (15TM, 15TD) and the lift pins 15P. In addition, the wafer is placed onto and brought upward from the susceptor 15S by moving the lift pins 15P downward and upward, respectively.

Even in the process module 15 according to the modified example (and the substrate processing apparatus including the process module 15), the substrate transfer method according to the second and the third embodiments can be carried out. Therefore, the same advantages and effects thereof can be provided through the process module 15 according to the modified example.

While the present invention has been described with reference to the foregoing embodiments, the present invention is not limited to the disclosed embodiments, but may be modified or altered within the scope of the accompanying claims.

For example, while the substrate transfer mechanism 150 having the three substrate holding members 15U, 15M, 15D is explained with reference to FIGS. 3 through 12, the substrate transfer mechanism 150 may have four or more substrate holding members.

In addition, while the substrate transfer mechanism 150 is configured to be moved upward and downward by the elevation driving part 15Aa and the wafer is transferred between the transfer arm 16 and the substrate holding members 15U, 15M, 15D (15TU, 15TM, 15TD) in the above embodiments, the transfer arm 16 may be configured to be moved upward and downward instead of the substrate transfer mechanism 150 so that the wafer is transferred between the transfer arm 16 and the substrate holding members 15U, 15M, 15D (15TU, 15TM, 15TD).

Moreover, the elevation driving part 15Aa may be configured to independently move the substrate holding members 15T, 15M, 15D (15TU, 15TM, 15TD) instead of moving the entire substrate transfer mechanism 150.

Furthermore, while the process module including the substrate transfer mechanism 150 that has two substrate holding members 15U, 15D is used to carry out the substrate transfer method according to the fourth embodiment, the substrate transfer method can be carried out using the process module including the substrate transfer mechanism 150 that has three or more substrate holding members. In addition, the transfer arm 16 transfers the processed wafer WP1 out to the transport chamber 14 after the substrate holding member 15D transfers the unprocessed wafer WU1 into the process chamber 15b and returns to the home position without any wafer in the fourth embodiment. However, the transfer arm 16 may transfer the processed wafer WP1 to the transport chamber 14, during a period of time when the substrate holding member 15D transfers the unprocessed wafer WU1 into the process chamber 15b and returns to the home position without any wafer in the fourth embodiment.

Additionally, while the process module 15 has the buffer chamber 15a and the process chamber 15b with the gate valve GV2 therebetween, the process module may have only one chamber in which the substrate transfer mechanism 150 and the susceptor 15S are arranged, depending on a process carried out in the chamber.

While the substrate processing apparatus 10 includes the plural process modules 15 in the above explanation, the substrate processing apparatus 10 may include only one process module 15 in other embodiments. In addition, while the process chamber 15b of the process module 15 has only one susceptor 15S on which one wafer is placed in the above explanation, the process chamber 15b may include a wafer plate (wafer tray) in which plural wafers can be accommodated.

While the substrate holding member 15U and the like have the slits 15t having a curved shape and the substrate holding member 15TU and the like have the slits 15t having a linear shape, the shape of the slits 15t may be arbitrarily determined as long as the substrate holding member can reciprocate between the home position and the position above the susceptor 15S without being obstructed by the lift pins 15P and certainly hold the wafer. Specifically, the shape of the slits 15t is preferably determined in accordance with a direction of the movement (or a route) of the substrate holding member 15U (15TU) and the like.

In addition, the shape of the cutout part 15c may be arbitrarily determined as long as the transfer arm 16 that has proceeded into the buffer chamber 15a can relatively move upward or downward relative to the substrate holding members 15U (15TU) and the like.

While the substrate holding member 15U (15TU) and the like have the same number of the slits 15t as the number of the lift pins 15P in the susceptor 15S, and the slits 15t allow the corresponding lift pins 15P to pass therethrough horizontally and vertically in the above explanation, the substrate holding member 15U (15TU) and the like may be configured so that plural (e.g., two) lift pins 15P can pass through one slit 15t. For example, the substrate holding member 15TU may have one long slit and one short slit in the fifth embodiment, and the three lift pins 15P may be arranged accordingly so that two lift pins 15P pass through the long slit and one lift pin 15P pass through the short slit.

The substrate transfer methods according to the second through the fourth embodiments can be carried out not only independently but also in combination during one lot of wafers to be processed. Namely, the substrate transfer method according to the third embodiment can be changed to the substrate transfer method according to the fourth embodiment, as the situation demands, while a process is carried out with respect to one lot of wafers.

What is claimed is:

1. A process module comprising:
a substrate receiving part on which a substrate is placed and a process is carried out with respect to the substrate on the substrate receiving part; and
a substrate transfer mechanism including plural substrate holding members, each of which can be positioned in a first position where the substrate is transferred to/from a substrate transfer apparatus provided outside the process module and a second position above the substrate receiving part, wherein each of the substrate holding members can hold the substrate.

2. The process module of claim 1, further comprising an elevation part that moves the substrate transfer mechanism upward/downward.

3. The process module of claim 1, further comprising a pivot mechanism that pivots each of the substrate holding members around a predetermined pivot axis between the first position and the second position.

4. The process module of claim 3, wherein a pivoting angle of each of the substrate holding members pivoted by the pivot mechanism is 90° or less.

5. A substrate processing apparatus comprising:
the process module recited in claim 1, wherein the substrate transfer apparatus can transfer the substrate to/from any of the plural substrate holding members that is positioned in the first position.

6. The substrate processing apparatus of claim 5, wherein the substrate receiving part is arranged in a process chamber that can be closed in an airtight manner;
wherein the substrate transfer mechanism is arranged in a buffer chamber that is in pressure communication with the process chamber; and
wherein the substrate transfer apparatus is arranged in a transport chamber to which one or plural of the buffer chambers may be coupled.

7. The substrate processing apparatus of claim 6, wherein the process chamber, the buffer chamber, and the transport chamber may be evacuated to a reduced pressure.

8. The substrate processing apparatus of claim 5, wherein the substrate transfer apparatus includes a first substrate holding area at one end and a second substrate holding area at the other end, the first and the second substrate holding areas being capable of holding the substrate, and
wherein the substrate transfer apparatus has a rotation center between the first and the second substrate holding areas.

9. A substrate transfer method of transferring a substrate between a substrate transfer apparatus and a substrate receiving part on which the substrate is placed and a process is carried out with respect to the substrate on the substrate receiving part, the substrate transfer method comprising steps of:
transferring a first substrate using the substrate transfer apparatus to and maintaining the first substrate in a first position;
transferring the first substrate maintained in the first position by the substrate transfer apparatus to a first one of plural substrate holding members, each of which can be positioned in the first position and a second position above the substrate receiving part and hold a substrate;
moving the first substrate holding member holding the first substrate to the second position; and
transferring a second substrate from a second one of the plural substrate holding members to the substrate transfer apparatus that has stayed in the first position.

10. The substrate transfer method of claim 9, further comprising a step of transferring the first substrate to the substrate receiving part from the first substrate holding member positioned in the second position.

11. The substrate transfer method of claim 9, wherein the first substrate holding member is moved upward in order to receive the first substrate from the substrate transfer apparatus in the step of transferring the first substrate to first substrate holding member.

12. The substrate transfer method of claim 9, wherein the first substrate holding member is pivoted around a predetermined pivot axis to reach the second position in the step of moving first substrate holding member to the second position.

13. The substrate transfer method of claim 12, wherein a pivoting angle of each of the plural substrate holding members is 90° or less.

14. The substrate transfer method of claim 9, wherein the second substrate holding member is moved downward in order to transfer the second substrate to the substrate transfer apparatus.

15. A substrate transfer method of transferring a substrate between a substrate transfer apparatus and a substrate receiving part on which the substrate is placed and a process is carried out with respect to the substrate on the substrate receiving part, the substrate transfer method comprising steps of:
transferring a first substrate held by a first one of plural substrate holding members, each of which can hold a substrate and be positioned in a first position and a second position that is above the substrate receiving part, to the second position;
transferring a second substrate using the substrate transfer apparatus to and maintaining the second substrate in the first position;
transferring the second substrate from the substrate transfer apparatus to a second one of the plural substrate holding members in the first position;
moving the first substrate holding member holding the first substrate from the second position to the first position; and
transferring the first substrate from the first substrate holding member to the substrate transfer apparatus in the first position.

16. The substrate transfer method of claim 15, wherein the first substrate holding member is pivoted around a predetermined pivot axis to reach the second position in the step of transferring first substrate to the second position.

17. The substrate transfer method of claim 15, wherein the second substrate holding member is moved upward to receive the second substrate from the substrate transfer apparatus in the step of transferring the second substrate from the substrate transfer apparatus to the second substrate holding member.

18. The substrate transfer method of claim 15, wherein the first substrate holding member is pivoted around a predetermined pivot axis to reach the first position in the step of moving the first substrate holding member from the second position to the first position.

19. The substrate transfer method of claim 15, wherein the first substrate holding member is moved downward to transfer the first substrate to the substrate transfer apparatus in the step of transferring the first substrate from the first substrate holding member to the substrate transfer apparatus.

20. The substrate transfer method of claim 16, wherein a pivoting angle of the first substrate holding member is 90° or less.
